(19) United States
(12) Patent Application Publication
(10) Pub. No.: US 2023/0155562 A1
(43) Pub. Date: May 18, 2023

(54) AUDIO OUTPUT ADJUSTMENT

(71) Applicant: HEWLETT-PACKARD DEVELOPMENT COMPANY, L.P., SPRING, TX (US)

(72) Inventors: CHRISTOPHER ALLAN STEVEN, SPRING, TX (US); ISAAC LAGNADO, SPRING, TX (US); BRANDON ARON FLEISSIG, SPRING, TX (US)

(21) Appl. No.: 17/995,955

(22) PCT Filed: Apr. 21, 2020
(86) PCT No.: PCT/US20/29142

§ 371 Date: Oct. 11, 2022

(51) Int. Cl. H03G 5/16; H03G 5/00

(52) U.S. Cl. CPC H03G 5/165; H03G 5/005

(57) ABSTRACT

Example electronic devices that may be implemented to generate an audio output via a resonance are disclosed. A received resonance sample of an audio output is categorized with a neural network to obtain an inference profile. The received resonance sample corresponding with an equalization setting. The equalization setting for the audio output is adjusted based on the inference profile.

### BACKGROUND

A loudspeaker, or speaker, is an electroacoustic transducer, which converts an electrical audio signal into acoustic energy that can produce a corresponding sound. A sound source, such as a music recording or music track, is amplified via an audio power amplifier, and a resulting electrical audio signal is provided to the loudspeaker. A common example of a loudspeaker includes a dynamic speaker to produce sound from the electrical audio signal. The dynamic speaker includes a voice coil suspended near a permanent magnet. The voice coil is also coupled to a movable diaphragm. An alternating current electrical audio signal is provided to the voice coil. Passing an alternating current through the voice coil creates a magnetic field via induction. When the electrical audio signal causes the polarity of the magnetic field in the voice coil to be the same as the permanent magnet, the magnetic forces repel one another and the voice coil can push on the diaphragm. When the electrical audio signal causes the polarity of the magnetic field in the voice coil to be the opposite of the permanent magnet, the magnetic forces attract one another and the voice coil can pull on the diaphragm. Movement of the diaphragm causes changes in the air pressure, which provides the acoustic energy.

### BRIEF DESCRIPTION OF THE DRAWINGS

FIG. 1 is a block diagram illustrating an example electronic device.

FIG. 2 is a block diagram illustrating another example electronic device to implement the example electronic device of FIG. 1.

FIG. 3 is schematic diagram illustrating an example portable speaker in accordance with the example electronic device of FIG. 2.

FIG. 4 is a schematic diagram illustrating an example computing device in accordance with the example electronic device of FIG. 2.

FIG. 5 is a block diagram illustrating another example electronic device.

FIG. 6 is a flow diagram illustrating an example aspect of the example electronic device of FIG. 5.

FIG. 7 is a block diagram illustrating an example training of a neural network that is implemented in the example electronic devices illustrated in FIGS. 1 and 6.

### DETAILED DESCRIPTION

In contrast to a dynamic speaker, a vibration speaker is a loudspeaker that does not include a diaphragm. Rather, the voice coil is coupled to a movable plate included in an inducer, or exciter. The movable plate of the exciter is disposed against a surface to transfer vibrations into the surface to produce acoustic energy. Examples of a surface can include a table, a desk, a bookshelf, a wall, and a window. The exciter can be disposed on the table, desk, bookshelf, wall, and window, such as placed or laid down on the table, desk, and bookshelf and attached to or pressed against the wall or window. As current of the electrical audio signal alternates in the voice coil, the voice coil causes the movable plate to vibrate. The movable plate vibrates against the surface, which can cause sound corresponding with the electrical audio signal.

Resonance sound amplification devices incorporate vibration speakers to produce acoustic energy, such as sound, that corresponds with an electric audio signal. Examples of resonance sound amplification devices can include portable speakers, smart speakers, invisible speakers, audio output devices, and computing devices such as laptops, docks, and mobile devices. Resonance sound amplification devices are apt in circumstances of small form factors that have limited space for dynamic loudspeakers. Resonance sound amplification devices include an exciter that is disposed on a surface, and the exciter can cause the surface to vibrate and produce the sound. Often, the quality of the sound produced with the resonance sound amplification device is based on the surface on which the resonance sound amplification device is dispose. For instance, an exciter disposed on a desk may produce a sound of a first quality and the exciter disposed on a table or bookshelf may produce a sound of a different quality. In the case of a resonance sound amplification device implemented in a portable computing device or portable speaker, for example, the resonance sound amplification device may be disposed on many different surfaces, and the quality of the sound can vary depending on the surface on which the resonance sound amplification device is disposed.

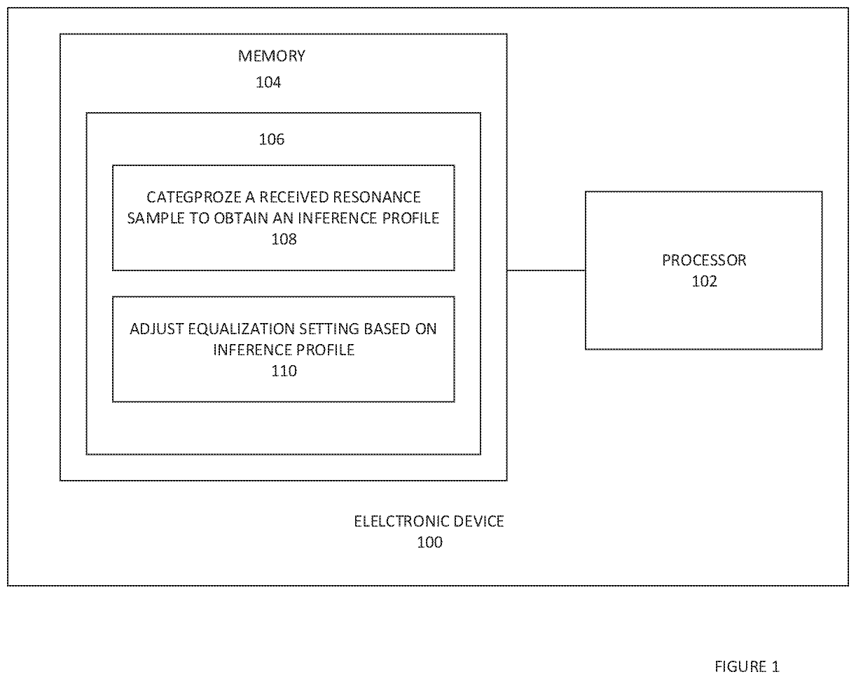

FIG. 1 illustrates an example electronic device 100. The electronic device 100 may be implemented with a resonance sound amplification device. In one example, the electronic device 100 includes a resonance sound amplification device. In another example, the electronic device 100 may be operably coupleable to a resonance sound amplification device. The example electronic device 100 can be implemented as a processor 102 and a non-transitory computer readable medium 104 comprising instructions 106. The electronic device 100 can include hardware devices, programs, or hardware devices and programs. For example, the non-transitory computer readable medium 104 can include a memory device to store the computer executable instructions 106 that when executed cause the processor 102 to perform a method. In one example, the computer executable instructions cause the processor to categorize a resonance sample of an audio output with a neural network to obtain an inference profile at 108. The received resonance sample corresponds with an equalization setting. The equalization setting for the audio output is adjusted based on the inference profile at 110.

In one example, the electronic device 100 includes a resonance sound amplification device to generate an audio output via a resonance. For instance, the resonance sound amplification device includes an exciter disposed on a surface to vibrate the surface and produce a sound. The exciter can be included in a vibration speaker and can receive an electrical audio signal having an equalization setting, such as a first equalization setting. The exciter vibrates against the surface, which can cause the audio output corresponding with the electrical audio signal. For example, the exciter includes a movable plate or member to cause a vibration. In one example, the surface is external to the resonance sound amplification device and not included as part of the resonance sound amplification device. The audio output can include an audible range of frequencies and an inaudible range of frequencies.

A resonance sample of the audio output is detected and received. For example, the audio output can be generated over a period of time, and the resonance sample of the audio output can include a subset of time of the period of time. In one example, the resonance sample is detected via a transducer disposed on the surface. The transducer may include an accelerometer. The transducer converts the vibrations on the surface into an electrical input signal, and the electrical input signal, or a portion of the electrical input signal, is applied as the resonance sample. In another example, the resonance sensor is detected by another sensor such as a microphone or other sensor that can detect vibrations such as a camera.

The received resonance sample of the audio output is categorized in an example at 108. For example, the received resonance sample of the audio output is categorized to quantifiably determine the nature and quality aspects of the audio output based on the received resonance sample. Aspects of the audio output based on the received resonance sample can include the type of corresponding audio recording, such as whether the audio recording is music speech or whether the audio recording is a music track and can include the type of music track such as whether the music track is of classic rock or classical music. Further, the received resonance sample can represent a recording of a performance in a live concert hall or a studio recording. Further, aspects of the received resonance sample include the resonance and characteristics of the surface, such as whether the surface is relatively large or relatively small, or the type of material of the surface. In an additional example, the aspects of the received resonance can account for the equalization settings applied to the audio output, such as the aspects of the received resonance can include the first equalization setting. In one example, the received resonance sample is transformed into a determined profile.

The received resonance sample of the audio output is categorized with a neural network to determine the inference profile in an example at 108. For example, the received resonance sample can be converted to a spectrograph, such as an audio spectrograph in the time domain, included in a determined profile. In one example, the determined profile is compared to a library of stock profiles to determine a match or a close approximation. The spectrograph compared to other audio spectrographs having known aspects. The other audio spectrographs can be included in a library of spectrographs. In one example, a deep neural network is used in the comparison. A deep neural network is an example of a neural network having multiple layers between an input and output. An example of a deep neural network suitable for use to categorize the received resonance samples includes a convolutional neural network, or CNN. The CNN can output the inference profile.

In one example, the inference profile can be associated with or correspond with an inference profile equalization setting. The equalization setting can alter features of the audio data associated with the electrical audio signal including frequency response, time response, and phase response. In one example, the equalization setting can be affected via the application of analog filters or digital filters. For instance, filters can be applied to the audio data to adjust bass and treble tones in an example equalizer or equalizer component.

The equalization setting for the audio output, such as the equalization setting that is applied to generate the audio output, can be adjusted based on the inference profile in an example at 110. For instance, an equalizer applied to audio data used to generate the electrical audio signal can be adjusted from the first equalization setting to the designated equalization setting corresponding with the inference profile. In another example, the equalizer applied to audio data used to generate the electrical audio signal can be adjusted from the first equalization setting to a setting approximating the designated equalization setting corresponding with the inference profile. In one example, the electronic device can be coupleable to a resonance sound amplification device to adjust the equalization setting at 110.

In one example, the method can be repeated for the audio output. In this example, the received resonance sample is periodically received, or a periodically received resonance sample. For example, the method can be repeated every selected amount of time, for a threshold change in the electrical audio signal, or for a change in track for a periodically received resonance sample.

In one example, the audio output used for the received resonance sample is a user-selected audio output played with the resonance sound amplification device. Examples of the user-selected audio output can include a music track, a conversation, and audio from an audio/video that is played with the resonance sound amplification device. In another example, the audio output is a device-selected audio output played with the resonance sound amplification device. The device-selected audio output can be generated via the processor used to categorize the received resonance sample. For instance, the device-selected audio output may be played to tune the resonance sound amplification device to the surface and include a known or a predetermined frequency and phase. The device-selected audio output can include a plurality of predetermined frequencies and phases output concurrently or over time. In still another example, the audio output can include a combination of a user-selected audio output and a device-selected audio output. In one example, the user-selected audio output may be determined to include a preponderance of low frequencies, and the device-selected audio output may be generated to include a higher frequency to tune the resonance sound amplification device in anticipation of, for example, subsequent music tracks. The device-selected audio output can be selected from an audible range of frequencies and an inaudible range of frequencies.

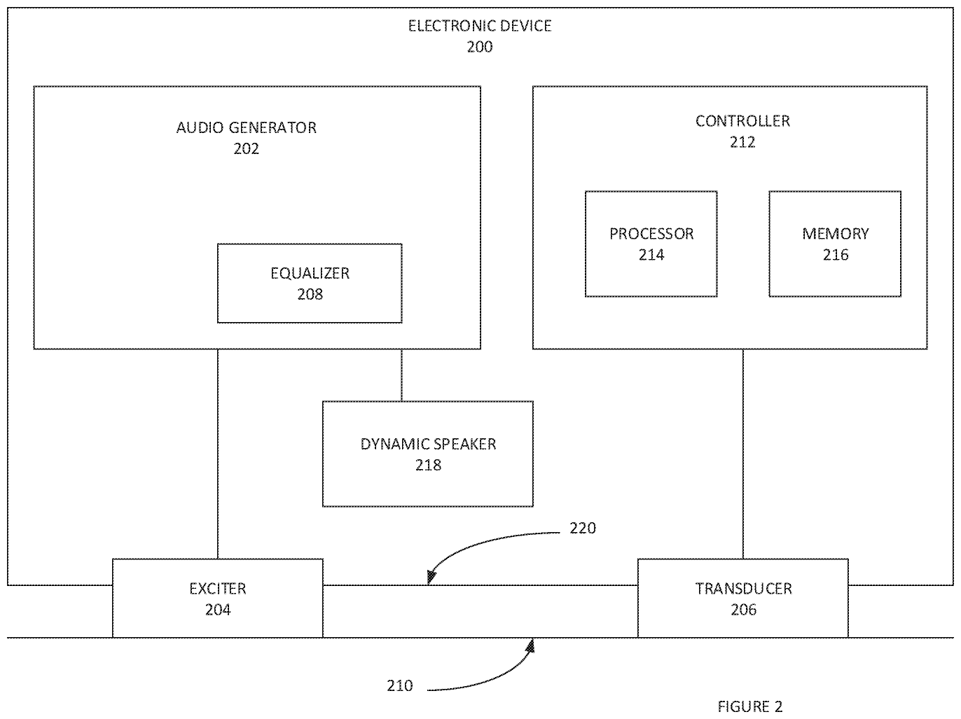

FIG. 2 illustrates an example electronic device 200 that includes a resonance sound amplification device. In one example, the electronic device 200 can be used to implement electronic device 100. The electronic device 200 can include an audio generator 202, an exciter 204, and a transducer 206. An example of a transducer 206 can include an accelerometer. In some examples, the electronic device 200 can also include a dynamic speaker. The audio generator 202 can receive a sound source such as a user-selected sound source such as a music recording, and generate an electrical audio signal. For example, the sound source can be received from a library of files or as a signal from a component such as receiver operably coupled to the audio generator 202. In some examples, the audio generator 202 can be coupled to various inputs to receive the sound source or a sound source signal such as wired or wireless connections. The electronic device 200 can include a sound source connection that the electronic device 200 can use to communicate with other audio components, computing devices, files or applications. Example sound source connections can include an audio left and right interface, USB connections, and a wireless communication interface.

The audio generator 202 can convert the sound source into audio data for processing. In the example, the audio generator 202 includes an equalizer 208. The equalizer 208 can apply an equalizer setting, such as the first equalizer setting to the audio data during processing to generate an electrical audio signal. The electrical audio signal is provided to the exciter 204. The exciter 204 generates a vibration corresponding with the electrical audio signal.

The vibration can be applied to a surface 210 if the exciter is disposed against the surface 210. The surface 210 is external to and separate from the electronic device 200. In the example, the exciter 204 is disposed on the surface 210, and the exciter 204 can cause the surface to vibrate and generate an audio output, such as a sound, corresponding with the electrical audio signal. The input transducer 206 receives the audio output and generates a transducer signal based on the received audio output. The transducer 206, such as an accelerometer, in one example, can be disposed on the surface 210. For instance, the components of the electronic device 200 can be enclosed in a case 220, and the exciter 204 and an accelerometer may extend from the case 220 as feet of the electronic device 200. In some examples, the electronic device 200 can include a plurality of exciters to provide independent audio channels or to focus or direct vibrations. The electronic device 200 can also include a plurality of transducers 206 including a plurality of different types of transducers such as an accelerometer and a microphone.

The electronic device 200 also includes a controller 212 to receive the transducer signal from the transducer 206. The controller 212, in one example, includes a processor 214 and memory 216. The memory 216 stores computer executable instructions. The processor 214 executes the instructions to generate a resonance sample of the audio output from the transducer signal. The processor 214 also executes the instructions to categorize the resonance sample of an audio output with a neural network, such as a CNN, to obtain an inference profile. The processor 214 is operably coupled to the audio generator 202, and the processor 214 executes the instructions to adjust the selected equalization setting for the audio output based on the inference profile. The audio generator 202 can apply the adjusted equalization settings to the sound source to produce the audio electrical signal.

In one example, the processor 214 may include a plurality of main processing cores to run an operating system and perform general-purpose tasks on an integrated circuit. The processor 214 may also include built-in logic or a programmable functional unit, also on the same integrated circuit with a heterogeneous instruction-set architecture. In additional to multiple general-purpose, main processing cores and the application processing unit, controller 212 can include other devices or circuits such as graphics processing units, neural network processing units, and an audio decoder/encoder, which may include heterogeneous or homogenous instruction set architectures with the main processing cores. For example, the controller 212 may be used to perform other tasks such as in the case of a computing device including the resonance sound amplification device. Additionally, features of the audio generator 202 may be included in or performed with the controller 212.

Memory 216 is an example of computer storage media. Computer storage media includes RAM, ROM, EEPROM, flash memory or other memory technology, CD-ROM, digital versatile discs (DVD) or other optical storage, magnetic cassettes, magnetic tape, magnetic disk storage or other magnetic storage devices, USB flash drive, flash memory card, or other flash storage devices, or other storage medium that can be used to store the desired information and that can be accessed by the processor 214. Accordingly, a propagating signal by itself does not qualify as storage media. Any such computer storage media may be part of the electronic device 200 and implemented as memory 216.

In some examples, the electronic device 200 can include a dynamic speaker 218 coupled to the audio generator 202 to generate an audio output. The audio generator 202 can selectively implement the dynamic speaker 218, such as to produce an audio output instead of the exciter 204, in addition to the exciter 204, or to not produce an audio output. For example, the dynamic speaker 218 can be applied to supplement the sound from the exciter 204 or instead of the exciter 204 in circumstances in which a vibration speaker may not be able to produce a sound that surpasses a quality threshold.

In one example, the electronic device 200 can be implemented using a laptop computer, a desktop computer, a tablet computer, a smart phone, etc. In such cases, the electronic device 200 can include additional components such as display, touchscreen, and keyboard. In other examples, the electronic device 200 can be implemented as an audio component including elements to store and execute computer readable instructions such as a portable speaker with a transducer 206 and a controller 212, such as an onboard processing circuit. In some examples, the electronic device 200 may include connections with the audio generator 202 that are coupleable to other audio output devices such as dynamic speakers or other vibration speakers.

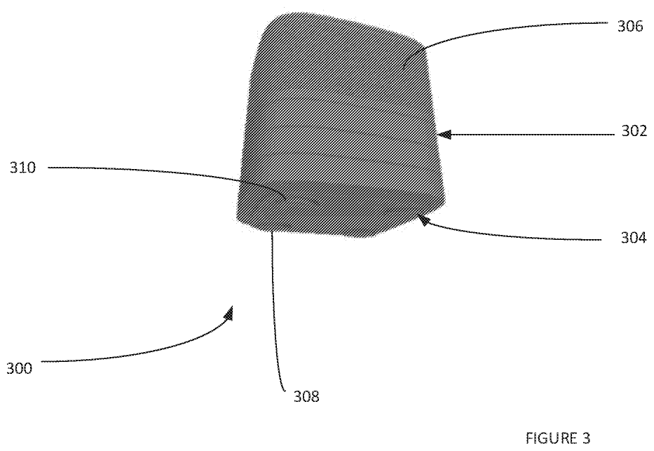

FIG. 3 illustrates an example portable speaker 300 in accordance with the electronic device 200. In the example, portable speaker 300 is implemented as a resonance sound amplification device to produce a sound via transducers disposed on a surface. In the example, portable speaker 300 can include a case 302 and feet 304. The case 302 can include components such as an audio generator and a controller stored within the case 302. In the example, the components can include audio source input components such as a communication circuitry. An example of communication circuitry can include a hardware that complies with a wireless technology standard to exchange data between electronic device such as the Bluetooth standard. The case may also be constructed to include an audio source input, such as a 3.5 mm auxiliary input or USP port. In the example, the case 302 includes a grill 306 behind which is disposed a dynamic speaker. The feet 304 extend from a side of the case 302, such as the underside of the case, and can be disposed on a surface in an operating arrangement of the resonance sound amplification device. A foot 308 of feet 304 includes an exciter, such as exciter 204, operably coupled to the audio generator, and another foot 310 of the feet 304 includes a transducer, such as transducer 206, operably coupled to the controller. In one example, two of the feet 304 include exciters operably coupled to the audio generator and can generate multiple sound channels, such as via stereo resonators. In one example, two of the feet 304 include transducer operably coupled to the controller and can receive multiple sound channels, such as via stereo accelerometers.

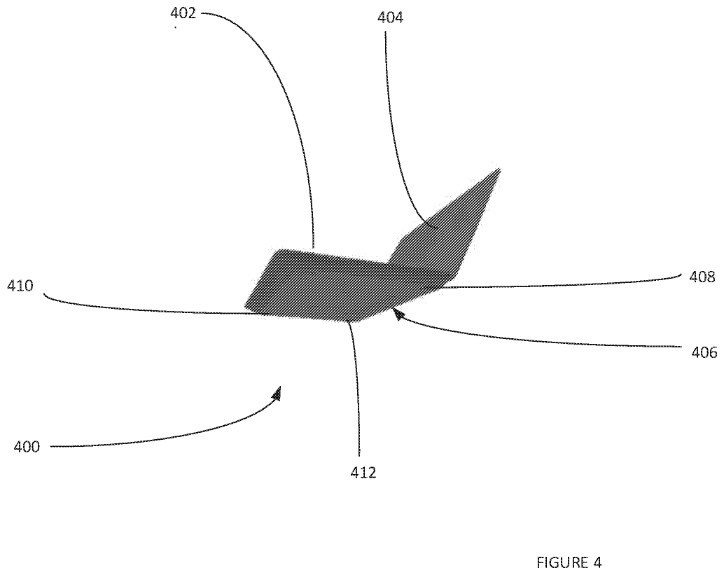

FIG. 4 illustrates an example general-purpose computing device 400, such as a laptop or tablet, in accordance with the electronic device 200. In the example, computing device 400 can include a keyboard 402 a display 404, and a touchscreen. The computing device 400 is implemented as a resonance sound amplification device to produce a sound via transducers disposed on a surface. In the example, computing device 400 further includes a case 406 and feet 408. The computing device 400 can include components such as an audio generator and a controller stored within the case 406. In the example, the audio generator and controller are combined in a processor on a motherboard within the case 406. The feet 408 extend from the case 406, such as from the underside of the case, and can be disposed on a surface if the computing device 400 is placed on the surface. A foot 410 of feet 408 includes an exciter, such as exciter 204, operably coupled to the audio generator, and another foot 412 of the feet 408 includes a transducer, such as transducer 206, operably coupled to the controller. In one example, two of the feet 408 include exciters operably coupled to the audio generator and can generate multiple sound channels, such as via stereo resonators. In one example, two of the feet 408 include transducer operably coupled to the controller and can receive multiple sound channels, such as via stereo accelerometers. In one example, the transducers include a microphone and camera, which may include additional features and functionality for the computing device, operably coupled to the controller.

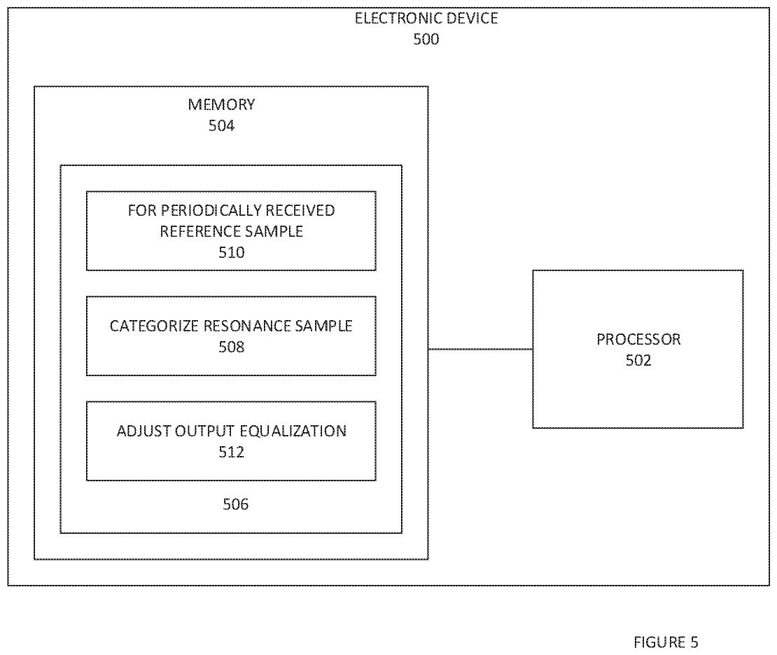

FIG. 5 illustrates an example electronic device 500. The electronic device 500 may be implemented with a resonance sound amplification device. In one example, the electronic device 500 includes a resonance sound amplification device. In another example, the electronic device 500 may be operably coupleable to a resonance sound amplification device. The example electronic device 500 can include a processor 502 and a non-transitory computer readable medium 504 comprising instructions 506. The electronic device 500 can include hardware devices, programs, or hardware devices and programs. For example, the non-transitory computer readable medium 504 can include a memory device to store the computer executable instructions 506 that when executed cause the processor 502 to perform a method. In one example, for audio output corresponding with an audio output equalization setting, the computer executable instructions cause the processor to categorize the resonance sample with a neural network to determine an inference profile equalization setting at 508 for a periodically received resonance sample of an audio output at 510. The audio output equalization setting is adjusted based on the inference profile equalization at 512.

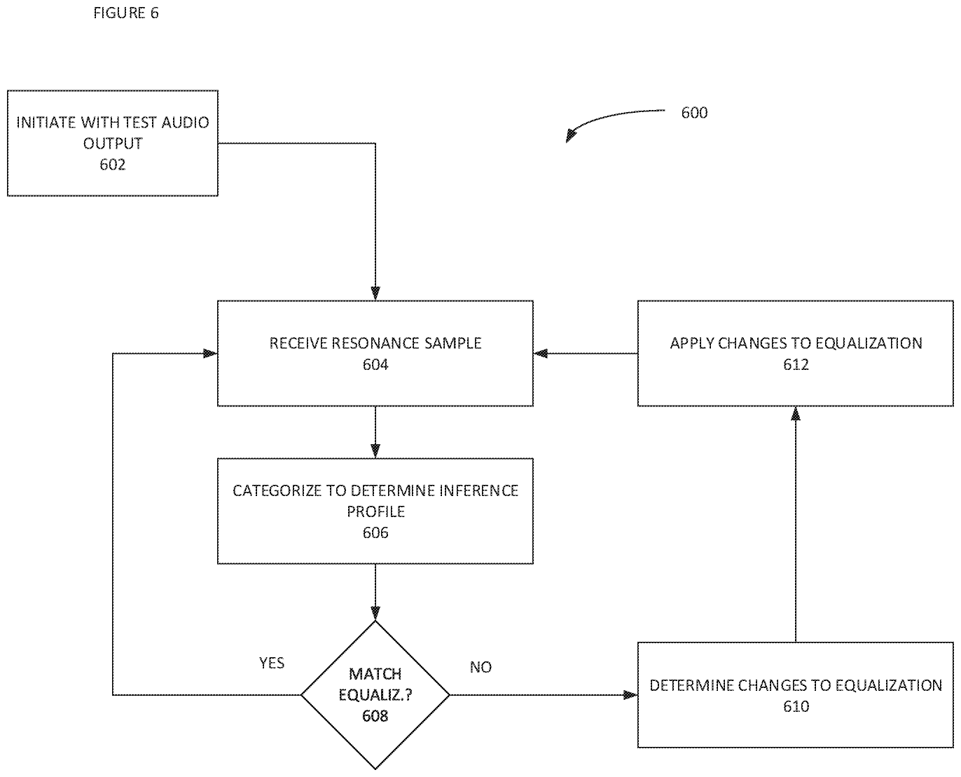

FIG. 6 illustrates an example method 600 that may be implemented with the instructions 506 of the non-transitory computer readable medium 504. For illustration, the example method 600 is implemented with electronic device 200 of FIG. 2. In one example, the method 600 may include an initiation feature to initiate an audio output at 602 during which a test audio output is generated with the exciter 204, and a transducer 206 generates a transducer signal from the audio output, and provides the transducer signal to a controller 212. Based on the transducer signal at the initiation feature 602, the controller 212 can determine whether the exciter 204 is suitable for use to produce a user-generated audio output, such as whether a determined sound quality of the test audio output has passed a threshold amount. For example, the surface 210 on which the exciter 204 is disposed may not be able to produce an acceptable sound or the exciter 204 is not disposed on a surface. If, for example, the exciter 204 is not suitable for use to produce an acceptable user-generated audio output, the electronic device 200 may produce an audio output via a dynamic speaker rather than a vibration speaker. If, for example, the exciter 204 is suitable for use to produce an acceptable user-generated audio output, the electronic device 200 may implement the vibration speaker to generate the audio output, such as implement the vibration and a dynamic speaker to generate the sound. If, for example, the exciter 204 is suitable for use to produce an acceptable user-generated audio output, the initiation feature 602 can be used to set an initial equalization setting for the electronic device 200.

A resonance sample of the audio output is received at 604. The transducer 206 is applied to receive the audio output and produce a transducer signal to the controller 212. The transducer signal can be applied as the resonance sample or the transducer signal can be sampled to produce the resonance sample. A transducer 206 can be used to detect the vibrations directly from the surface or vibrations in a medium such as air. In some examples, multiple transducers can be applied to generate multiple transducer signals.

The resonance sample is categorized to generate an inference profile at 606. In one example, the resonance sample can be categorized via a CNN using a co-processor device such as a neural network processor for processor 214. The generated inference profile corresponds with an equalization setting. The equalization setting of the inference profile is compared with the equalization setting of the audio generator 202.

If the equalization setting of the inference profile is a match with the equalization setting of the audio generator at 608, in which a match is if the equalization setting of the audio generator is the same or within an accepted threshold of the equalization setting of the inference profile audio generator, no changes are made to the equalization setting of the audio generator. Another resonance sample of the audio output can be received at 604, such as in a subsequent music track, after an amount of time has elapsed, if a characteristic of the audio output have been changed via a threshold amount, such as if bass and treble frequency characteristics of the audio output have been changed enough as predetermined in the electronic device 200.

If the equalization setting of the inference profile is not a match with the equalization setting of the audio generator at 608, in which a not a match is if the equalization setting of the audio generator is outside of an accepted threshold of the equalization setting of the inference profile audio generator, the changes to the equalization setting of the audio generator to match the equalization setting of the inference profile are determined at 610. The determined changes to the equalization setting of the audio generator to match the equalization setting of the inference profile are applied to the audio generator 202 such as to the equalizer 208 at 612. Another resonance sample of the audio output can be received at 604, such as in a subsequent music track, after an amount of time has elapsed, if a characteristic of the audio output has been changed by a threshold amount.

In some circumstances, errors may be generated in the method 600. For example, the categorization at 600 may at times not produce an inference profile, such as if the exciter 204 has been moved and is not on a surface, or the determined changes to the equalization setting at 610 are outside the scope of the equalizer 208. In such circumstances, method 600 may revert to features including initialization at 602, sampling again at 604, and disabling the exciter and enabling dynamic speaker 218.

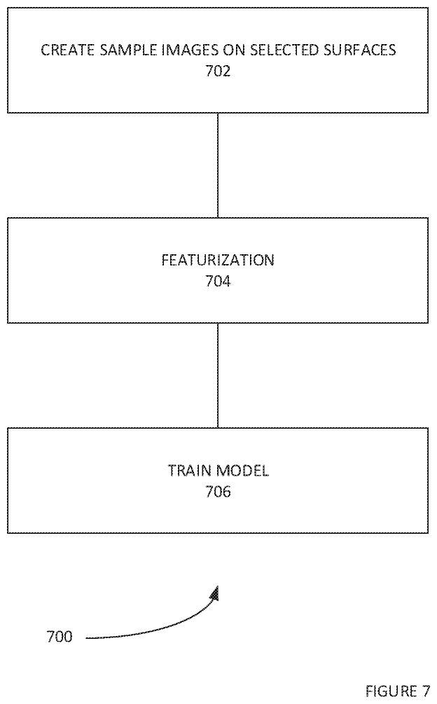

FIG. 7 illustrates an example methodology 700 to generate a categorization model. Sample images on selected surfaces are created at 702. For example, the sample images can include tagged sample images under controlled and, in some examples, desirable conditions. In one instance, the desirable conditions can include disposing the exciter on an aluminum or copper surface to generate the sound. The vibrations of the surface used to generate the sound are received with a transducer, and the transducer signal is converted to an image for use in a CNN via featurization at 704. In one example, a Fast Fourier Transform is applied to the transducer signal, to which a Hamming is applied, and a spectrogram is created. The spectrogram includes features that are mapped to a mel scale. The model is trained using equalizer profiles as tag classifications. In one example, the equalizer profiles can correspond with the equalizer profiles of the intended electronic device. In an example in which the electronic device is a computing device, the equalizer profile can correspond with an equalizer profile of the operating system to be run with the computing device. In one example, the training can be performed with an Adam optimizer. The model can be tested, refined, and subsequently implemented with the electronic device to perform the categorization features.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A non-transitory computer readable medium comprising instructions when executed cause a processor of an electronic device to:
categorize a received resonance sample of an audio output with a neural network to obtain an inference profile, the received resonance sample corresponding with an equalization setting; and
adjust the equalization setting for the audio output based on the inference profile.

2. The non-transitory computer readable medium of claim 1 wherein the inference profile is associated with an inference profile equalization setting, and wherein the instructions when executed further cause the processor to adjust the equalization setting based on the inference profile equalization setting.

3. The non-transitory computer readable medium of claim 2 wherein the equalization setting is adjusted to be the inference profile equalization setting.

4. The non-transitory computer readable medium of claim 1 wherein the neural network includes a convolutional neural network.

5. The non-transitory computer readable medium of claim 1 wherein the instructions when executed further cause the processor to convert the received resonance sample to a spectrograph.

6. The non-transitory computer readable medium of claim 1 wherein the audio output is a user-selected audio output, a device-selected audio output, or a combination thereof.

7. The non-transitory computer readable medium of claim 1 wherein the received resonance sample is a periodically received resonance sample.

8. An electronic device comprising:
a resonance sound amplification device including:
a sound exciter to generate an audio output against a surface based on an audio signal produced from an equalization setting;
a transducer to receive the audio output and to generate a transducer signal based on the received audio output; and
a controller to:
generate a resonance sample of the audio from the transducer signal;
categorize the resonance sample of an audio output with a neural network to obtain an inference profile; and
adjust the equalization setting for the audio output based on the inference profile.

9. The resonance sound amplification device of claim 8 wherein the transducer is an accelerometer.

10. The resonance sound amplification device of claim 8 further comprising a case, wherein the sound exciter and the transducer extend from the case.

11. The resonance sound amplification device of claim 8 comprising an audio generator operably coupled to the controller and the sound exciter, the audio generator to apply the equalization setting.

12. The resonance sound amplification device of claim 11 further comprising a dynamic speaker operably coupled to the audio generator.

13. A non-transitory computer readable medium comprising instructions when executed cause a processor of an electronic device to:
for a periodically received resonance sample of an audio output, the audio output corresponding with an audio output equalization setting:
categorize the resonance sample with a neural network to determine an inference profile equalization setting; and
adjust the audio output equalization setting based on the inference profile equalization.

14. The non-transitory computer readable medium of claim 13 including initiating the audio output via a test audio output.

15. The non-transitory computer readable medium of claim of claim 13 wherein the periodically received resonance sample is received when a characteristic of the audio output has changed by a threshold amount.
